(19) United States
(12) Patent Application Publication
(10) Pub. No.: US 2011/0169093 A1
(43) Pub. Date: Jul. 14, 2011

(54) ELECTROSTATIC DISCHARGE PROTECTION DEVICE FOR HIGH VOLTAGE OPERATION

(75) Inventor: Kilho Kim, Icheon-si (KR)

(73) Assignee: BAUABTECH

(21) Appl. No.: 12/985,367

(22) Filed: Jan. 6, 2011

(30) Foreign Application Priority Data
Jan. 8, 2010 (KR) 10-2010-0001611

(51) Int. Cl. H01L 29/78

(52) U.S. Cl. 257/361; 257/E29.258

(57) ABSTRACT

The present disclosure provides ESD protection devices that can effectively cope with electrostatic stress of microchips for high voltage operation. The ESD protection device is a double diffused drain N-type MOSFET (DDDNMOS) ESD protection device, in which a gate, a source region and a well-pickup region are connected to a ground terminal and a drain region is connected to a power terminal or individual input/output terminals. The ESD protection device includes a first conductive type well region formed in a semiconductor substrate, a gate formed to on the semiconductor substrate, a second conductive type source region and a drain region formed in the well region at opposite sides of the gate, a first conductive type well-pickup region formed at one side of the source region, a first conductive type pocket region formed in the well region to surround the source region, a second conductive type drain drift region formed in the well region to surround the drain region, and a first conductive type divot region formed in the drain drift region between a side surface of the gate and the drain region.

### FIELD OF THE TECHNOLOGY

The present disclosure relates to semiconductor devices and, more particularly, to an improved electrostatic discharge protection device for high voltage operation.

### DESCRIPTION

In general, semiconductor devices include an electrostatic discharge (ESD) protection circuit between a pad and a core circuit to protect the core circuit. The electrostatic discharge protection circuit prevents chip failure that is likely to occur when static electricity caused by contact between an external pin of a microchip and a charged human body or machine is discharged to a core circuit or when accumulated static electricity flows to the core circuit. In fabrication of microchips, it is an essential aspect of chip design to design a circuit for protecting a microchip from ESD stress. A device for use in the protection circuit to protect against the ESD stress is referred to as an ESD protection device. The ESD protection device must satisfy the fundamental requirements described below.

FIG. 1 is a graphical representation of fundamental requirements of an electrostatic discharge protection device.

The ESD protection device must prevent current flow therethrough to the ESD protection device upon application of voltage less than or equal to an operating voltage Vop during normal operation of a microchip adopting the ESD protection device. In order to satisfy this requirement, the avalanche breakdown voltage Vav and the triggering voltage Vtr of the ESD protection device must be greater than the operating voltage of the microchip during normal operation (Vav, Vtr>Vop).

The ESD protection device must be able to provide sufficient protection to a core circuit in the microchip when the microchip is subjected to electrostatic discharge stress. In other words, when electrostatic current flows to the microchip, it must be discharged to the outside through the ESD protection device before flowing to the core circuit. To satisfy this requirement, the triggering voltage Vtr of the ESD protection device must be sufficiently lower than the core circuit breakdown voltage Vccb of the microchip when ESD stress is generated in the microchip (Vtr<Vccb).

Generally, an efficient ESD protection device exhibits a resistance snapback characteristic wherein on-state resistance of the ESD protection device is reduced after the device is triggered. Such a resistance snapback characteristic is exhibited as a voltage snapback phenomenon wherein the corresponding voltage is lowered, despite an increase in current flowing through the ESD protection device. Here, if the snapback phenomenon becomes too severe, the ESD protection device suffers a latch-up phenomenon which allows excess current to flow through the ESD protection device, thereby causing thermal breakdown of the microchip, even when the microchip is normally operated. The ESD protection device must be prevented from abnormal operation resulting from the latch-up phenomenon. To satisfy this requirement, the snapback holding voltage Vh of the ESD protection device must be greater than the operating voltage of the microchip by a sufficient safety margin (Vh>VoP+ΔV). Alternatively, the triggering current Itr must be sufficiently greater than a certain value (Itr>˜100 mA).

The ESD protection device generally adopts a multi-finger structure wherein devices having a constant size are arranged in parallel to each other for efficient use of a layout area. When such a multi-finger structure is adopted, it is necessary for the respective fingers of the ESD protection device to operate uniformly. In other words, the respective fingers of the ESD protection device cooperate to discharge induced electrostatic discharge current to the outside.

To this end, other fingers must also be triggered to cooperatively discharge the ESD current before a certain finger is triggered and suffers thermal breakdown. To satisfy this requirement, the thermal breakdown voltage Vtb of the ESD protection device must be greater than or at least similar to the triggering voltage (Vtr≦Vtb) thereof.

On the other hand, one fundamental requirement of semiconductor devices operating at high voltage is that the avalanche breakdown voltage must be higher than the operating voltage. To satisfy this requirement, the semiconductor device employs, as a basic element, an N-type MOSFET having a double diffused drain, that is, a double diffused drain N-type MOSFET (DDDNMOS), as shown in FIG. 2.

In order to construct the DDDNMOS structure, double impurity implantation for drain formation is performed as shown in FIG. 2. In the DDDNMOS structure, a drain activation area 121 is formed by implanting an impurity at a sufficiently high density of 10¹⁵˜10¹⁶ cm⁻³, and a drain drift area 120 is formed outside the drain activation area 121 by implanting an impurity at a relatively low density of about 10¹³ cm⁻³. In most cases, a source activation area 130 has the same impurity density as the drain activation area 121 since they are formed at the same time by the impurity implantation. A P-well 110 forming a channel is formed by implanting a P-type impurity at a density of about 10¹² cm⁻³, which is lower than the drain drift area 120. Generally, the avalanche breakdown voltage tends to increase as two adjoining areas having opposite polarity decrease in impurity density. Hence, since the DDDNMOS structure enables sufficient reduction of the impurity density for the drain drift area 120 which adjoins the P-well 101, it is possible to achieve a desired high avalanche breakdown voltage.

In order to use the DDDNMOS as the ESD protection device for high voltage operation, a gate 150, a source 130 and a well-pickup 140 are bundled and is connected to a ground terminal on a circuit, with only the drain 121 connected to a power terminal or individual input/output terminals, thereby forming a grounded gate DDDNMOS (GGDDDNMOS), as shown in FIG. 2. With this electrode structure, the GGDDDNMOS does not allow electric current to flow therethrough during normal operation of the microchip since the gate of the NMOSFET is grounded. Further, the GGDDDNMOS does not allow electric current to flow therethrough when voltage applied to the drain is lower than the avalanche breakdown voltage. On the other hand, when the voltage applied to the drain rises above the avalanche breakdown voltage, impact ionization occurs at an interface between the P-well and the drain drift region, thereby generating a number of carriers, so that a parasitic NPN bipolar transistor is formed, causing a large amount of electric current to flow between the drain and the source. Consequently, the GGDDDNMOS does not allow electric current to flow therethrough at a voltage less than the avalanche breakdown voltage while allowing the current to flow therethrough at a voltage above the avalanche breakdown voltage, thereby satisfying fundamental requirements of the ESD protection device which protects a core circuit by coping with undesired stress current during electrostatic discharge. To increase ESD stress current treatment capabilities, a multi-finger GGDDDNMOS is provided by connecting several single-finger GGDDDNMOS devices in parallel to each other.

Here, when a parasitic NPN bipolar transistor (BJT) is created in the GGDDDNMOS to allow a large amount of current to start to flow therethrough, a very low resistance surface current path is formed to connect the drain/channel/source regions to each other along the surface of the device, causing current crowding only on the device surface. Such current crowding on the device surface causes some problems as follows in use of the GGDDDNMOS as an ESD protection device.

FIG. 3 is a graphical representation of typical voltage-current characteristics of a GGDDDNMOS device operating as an ESD protection device.

The current crowding on the device surface of the GGDDDNMOS causes a significant deterioration in the ability of the GGDDDNMOS to cope with ESD stress current. Specifically, when the current path is formed only along the device surface to limit current crowding to the device surface, a surface temperature of the device sharply rises even at low current, causing thermal breakdown at the surface of the device. As a result, the ability of the device to cope with the electrostatic current is significantly deteriorated.

Since the current path on the surface of the GGDDDNMOS device has very low resistance, on-state resistance of the NPN BJP of the GGDDDNMOS device is very low, causing an excessively strong snapback phenomenon. Here, the strong snapback phenomenon and the low on-state resistance of the NPN BJP of the GGDDDNMOS cause a latch-up phenomenon which allows excess electric current to flow through the ESD protection device, thereby causing thermal breakdown of the microchip, even when the microchip is normally operated.

The thermal breakdown voltage of the GGDDDNMOS becomes lower than the triggering voltage thereof, thereby making it difficult to achieve uniform operation of the respective fingers of the multi-finger structure.

Therefore, there is a need for an improved ESD protection device that can solve the problems of the GGDDDNMOS while exhibiting the properties of high avalanche breakdown voltage in order to effectively cope with electrostatic stress of microchips for high voltage operation.

### BRIEF SUMMARY

Aspects of the present disclosure provide improved electrostatic discharge protection devices that can effectively cope with electrostatic stress of microchips for high voltage operation.

According to one aspect of the present disclosure, there is provided a double diffused drain N-type MOSFET (DDDNMOS) electrostatic discharge (ESD) protection device, in which a gate, a source region and a well-pickup region are connected to a ground terminal and a drain region is connected to a power terminal or individual input/output terminals. The ESD protection device includes: a first conductive type well region formed in a semiconductor substrate; a gate formed on the semiconductor substrate; a second conductive type source region and a drain region formed in the well region at opposite sides of the gate; a first conductive type well-pickup region formed at one side of the source region; a second conductive type drain drift region formed in the well region to surround the drain region; and a first conductive type divot region formed in the drain drift region between a side surface of the gate and the drain region.

The ESD protection device may further include a second conductive type compensation region configured to surround the drain region and the divot region. The compensation region may be formed deeper than the drain drift region such that a lower end of the compensation region penetrates the drain drift region. A distance between an edge of the compensation region and an edge of the drain drift region may be adjusted to attain a desired avalanche breakdown voltage and triggering voltage of a bipolar transistor created in the device.

The divot region may be formed at an impurity density of 10¹⁵˜10¹⁶ cm⁻³ near the drain region.

According to another aspect of the present disclosure, there is provided a DDDNMOS electrostatic discharge (ESD) protection device, in which a gate, a source region and a well-pickup region are connected to a ground terminal and a drain region is connected to a power terminal or individual input/output terminals. The ESD protection device includes: a first conductive type well region formed in a semiconductor substrate; a gate formed on the semiconductor substrate; a second conductive type source region and a drain region formed in the well region at opposite sides of the gate; a first conductive type well-pickup region formed at to one side of the source region; a first conductive type pocket region formed in the well region to surround the source region; a second conductive type drain drift region formed in the well region to surround the drain region; and a first conductive type divot region formed in the drain drift region between a side surface of the gate and the drain region.

The ESD protection device may further include a second conductive type compensation region configured to surround the drain region and the divot region. The compensation region may be formed deeper than the drain drift region such that a lower end of the compensation region penetrates the drain drift region. A distance between an edge of the compensation region and an edge of the drain drift region may be adjusted to attain a desired avalanche breakdown voltage and triggering voltage of a bipolar transistor created in the device. The divot region may be formed at an impurity density of 10¹⁵˜10¹⁶ cm⁻³ near the drain region.

An impurity implantation condition may be adjusted to maximize an overlap margin between the pocket region and the source region while minimizing a depth margin of the pocket region to the source region in order to suppress flow of electric current on a surface of the device while promoting the flow of electric current in a depth direction of the device. The pocket region may be formed at an impurity density of 10¹³˜10¹⁴ cm⁻³.

The device may further include a second conductive type ballistic region formed centered on the drain region to surround the drain region or to be positioned inside the drain region.

The ballistic region may be formed centered on the drain region such that a bottom surface of the ballistic region is close to a bottom of the well region.

The device may further include a second conductive type trajectory region formed on the bottom of the well region to maximize current induction of the ballistic region.

The trajectory region may be formed in the well region so as to extend deeper than the drain drift region.

### BRIEF DESCRIPTION OF THE DRAWINGS

The above and other aspects, features and advantages of the present disclosure will become apparent from the following description of exemplary embodiments given in conjunction with the accompanying drawings, in which:

FIG. 1 is a graphical representation of fundamental conditions for an ESD protection device;

FIGS. 2a and 2b are a circuit diagram and a sectional view of a DDDNMOS device, to which include a drain formed through double-diffusion of impurities;

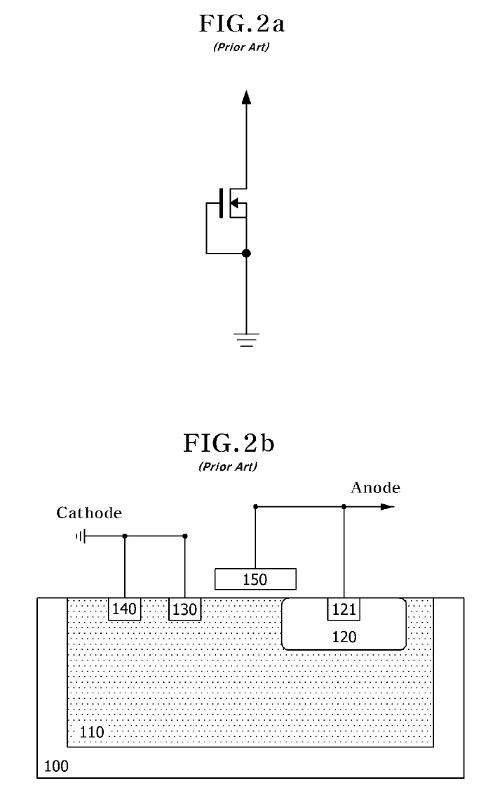

FIG. 3 is a graphical representation of typical voltage-current characteristics of a GGDDDNMOS device operating as an ESD protection device;

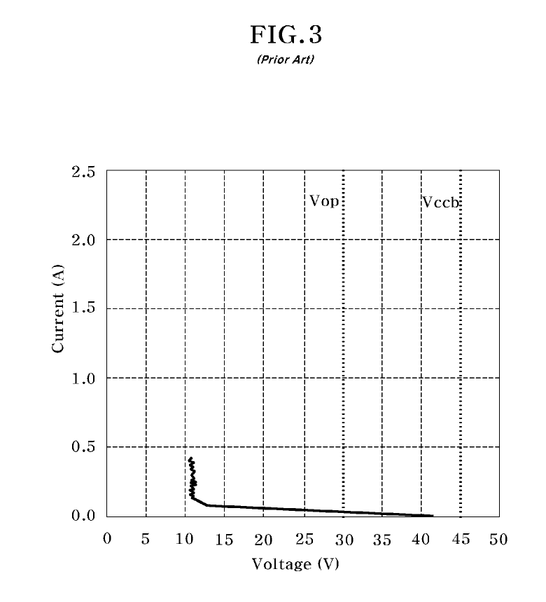

FIGS. 4a and 4b are a circuit diagram and a sectional view of an ESD protection device for high voltage operation according to one exemplary embodiment of the present disclosure;

FIG. 5 is a sectional view of an ESD protection device for high voltage operation according to another exemplary embodiment of the present disclosure; and

FIG. 6 is a graphical representation of voltage-current characteristics of an ESD protection device during normal operation and upon inflow of electrostatic current, according to the present disclosure.

### DETAILED DESCRIPTION

Exemplary embodiments will now be described in detail with reference to the accompanying drawings. It should be understood that the embodiments may be modified in various ways and are not intended to limit the scope of the present disclosure.

The inventors of the present disclosure suggest an ESD protection device that further includes a divot region (divot P+ implant region), that is, a divot implant applied double diffused drain NMOSFET (DIADDDNMOS), for blocking a surface current path having very low resistance and connecting drain/channel/source regions of GGDDDNMOS to each other to overcome the problems of the GGDDDNMOS ESD protection device.

Generally, the DDDNMOS maintains a constant distance between a gate and a drain and makes a drain drift region (drain N-drift region) close the gate or extends the drain drift region (drain N-drift region) to a lower region of the gate. To construct the DIADDDNMOS, a divot region (divot P+ implant region) is formed in margin between the gate and the drain to block a surface current path, which has very low resistance and connects drain/channel/source regions of the GGDDDNMOS to each other. Further, a compensation region (compensation N-implant region) is additionally formed to surround the drain and the divot region in order to compensate for current loss caused by the formation of the divot region.

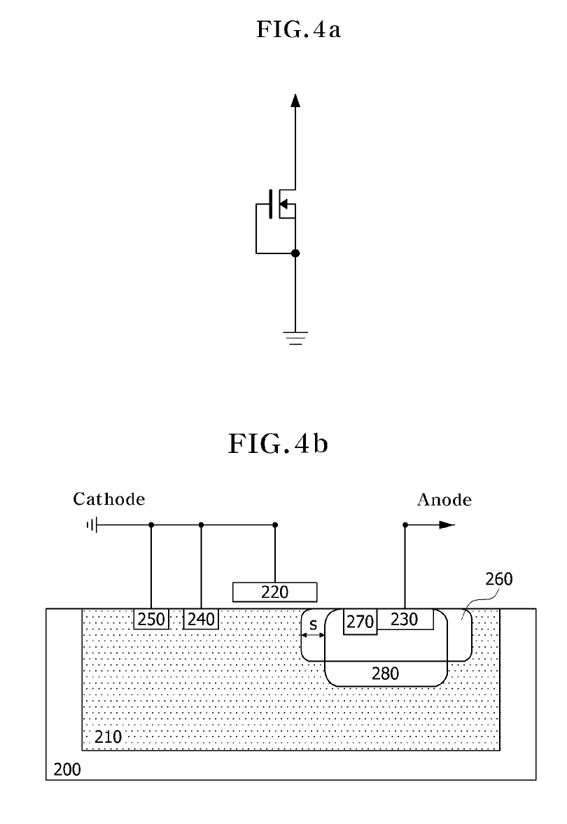

FIGS. 4a and 4b are a circuit diagram and a sectional view of an ESD protection device for high voltage operation according to one exemplary embodiment, respectively.

Referring to FIGS. 4a and 4b, in the ESD protection device for high voltage operation according to this embodiment, a high voltage P well 210 is formed on a P-type semiconductor substrate 200. Although conditions for forming the high voltage P well 210 through impurity implantation may be changed depending on processes, the high voltage P well 210 is formed at an impurity density of about 10¹² cm⁻³. A gate 220 is formed on the semiconductor substrate 200 in which the high voltage P-well 210 is formed. The gate 220 may be composed of, for example, an impurity-doped polysilicon layer. A drain region 230 and a source region 240 are disposed at opposite sides of the gate 220 in the high voltage P-well 210 to be separated a predetermined distance from each other. The drain region 230 and the source region 240 are doped with N-type impurities at a density of about 10¹⁵˜10¹⁶ cm⁻³. A P+ pickup region 250 is formed near one side of the source region 240 and has an impurity density of about 10¹⁵˜10¹⁶ cm⁻³. A drain drift region 260 is formed at an impurity density of 10¹³ cm⁻³ to surround the drain region 230, and a divot region 270 is formed near the drain region 230 in the drain drift region 260 between the gate 220 and the drain region 230. The divot region 270 serves to block a surface current path, which connects the drain/channel/source regions to each other and has very low resistance. The divot region 270 is formed at an impurity density of 10¹⁵˜10¹⁶ cm⁻³, which is similar to the impurity density of the drain region 230. An implantation depth of the divot region 270 may be similar to that of the drain region 230 and be increased or decreased to maximize characteristics of the ESD protection device, as needed.

Further, a compensation region 280 is formed to surround the drain region 230 and the divot region 270 in order to compensate for current loss caused by the formation of the divot region 270. The compensation region 280 is formed by implanting P-type impurities at a density of about 10¹³ cm⁻³, which is similar to that of the drain drift region 260, and has a slightly deeper implantation depth than the drain drift region 260, such that a lower end of the compensation region 280 can penetrate the drain drift region 260.

A distance “s” between the compensation region 280 and the drain drift region 260 determines an avalanche breakdown voltage and a triggering voltage of an NPN BJT operating in the DIADDDNMOS. In other words, when the distance “s” between the compensation region 280 and the drain drift region 260 is sufficiently increased, the avalanche breakdown voltage and the triggering voltage of the NPN BJT increase, and when the distance “s” is sufficiently decreased, the avalanche breakdown voltage and the triggering voltage of the NPN BJT decrease. Therefore, the avalanche breakdown voltage and the triggering voltage of the NPN BJT operating in the DIADDDNMOS may be adjusted to desired values by suitably adjusting the distance “s” between an edge of the compensation region 280 and an edge of the drain drift region 260.

The divot region 270 disposed between the gate and the drain region 230 serves to block the surface current path which has very low resistance and is generally formed in the existing DDDNMOS. Therefore, the device may overcome the problem of current crowding on the surface of the device during operation of the NPN BJT in the DDDNMOS. The compensation region primarily serves to compensate for current loss in a depth direction of the device when the current loss occurs due to the divot region. Further, the compensation region guides electric current tending to crowd only on the surface of the device to flow in the depth direction of the device, thereby allowing the current to flow through an overall surface of the device between an anode and a cathode.

When the divot region is disposed between the gate and the drain region, electric current tending to crowd on the surface of the device is blocked by the divot region, so that the avalanche breakdown voltage and the triggering voltage of the NPN BJT operation increase. On the contrary, since the impurities implanted to form the compensation region are the same N-type impurities as those for forming the drain drift region, the compensation region can reduce the avalanche breakdown voltage and the triggering voltage of the NPN BJT operation. Impurity implantation for forming the compensation region at the same density allows the avalanche breakdown voltage and the triggering voltage to be determined by the distance “s” between the edge of the compensation region and the edge of the triggering region. Accordingly, the overall avalanche breakdown voltage and triggering voltage of the DIADDDNMOS can be adjusted to desired voltages by suitably adjusting the distance “s” between the edge of the compensation region and the edge of the triggering region.

The DIADDDNMOS ESD protection device including the divot region and the compensation region according to the embodiment overcomes the problem of current crowding on the surface of the existing DDDNMOS device. As a result, the DIADDDNMOS ESD protection device according to the embodiment can solve problems occurring when the DDDNMOS is used as an ESD protection device. Further, the DIADDDNMOS device permits a desired avalanche breakdown voltage and triggering voltage of the NPN BJT to be attained by suitably adjusting the distance “s” between the compensation region and the drain drift region.

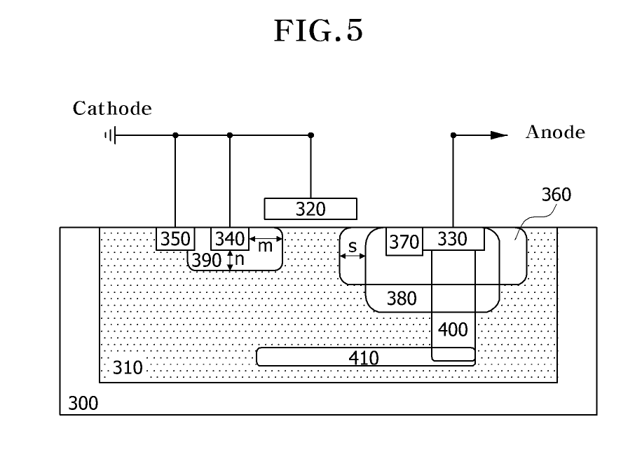

FIG. 5 is a sectional view of an ESD protection device for high voltage operation according to another exemplary embodiment of the present disclosure. The ESD protection device according to this embodiment may increase on-state resistance of the device while increasing a current immunity level of the device to electrostatic current.

Referring to FIG. 5, in the ESD protection device for high voltage operation according to this embodiment, a high voltage P well 310 is formed on a P-type semiconductor substrate 300. Although conditions for forming the high voltage P well 310 through impurity implantation may be changed depending on processes, the high voltage P well 310 is formed at an impurity density of about 10¹² cm⁻³. A gate 320 is formed on the semiconductor substrate 300 in which the high voltage P-well 310 is formed. The gate 320 may be composed of, for example, an impurity-doped polysilicon layer. A drain region 330 and a source region 340 are disposed at opposite sides of the gate 320 in the high voltage P-well 310 so as to be separated a predetermined distance from each other. The drain region 330 and the source region 340 are doped with N-type impurities at a density of about 10¹⁵˜10¹⁶ cm⁻³.

A P+ pickup region 350 is formed near one side of the source region 340 and has an impurity density of about 10¹⁵˜10¹⁶ cm^{˜3}. A pocket region (pocket P-implant region) 390 is formed to surround the source region 340. The pocket region 390 is formed by implanting P-type impurities at a density of about 10¹³˜10¹⁴ cm⁻³ to form a high density of holes. During operation of the NPN BJT, main carriers of electric current are electrons emitted from the source region. When the pocket region 390 is formed around the source region 340 to increase the density of holes, many electrons emitted from the source regions recombine with the holes, thereby obstructing the flow of electric current. Consequently, the on-state resistance of the NPN BJT increases. When the pocket region 390 is formed in the device, impurity implantation conditions may be adjusted to maximize an overlap margin between the pocket region 390 and the source region 340 while minimizing a depth margin of the pocket region 390 to the source region 340 in order to promote the flow of electric current in the depth direction of the device while suppressing the flow of electric current on the surface of the device. The pocket region 390 has an impurity density of about 10¹³˜10¹⁴ cm⁻³, which is greater than that of the high voltage P well region 310.

A drain drift region 360 is formed at an impurity density of 10¹³ cm⁻³ to surround the drain region 330, and a divot region 370 is formed near the drain region 330 in the drain drift region 360 between the gate 320 and the drain region 330. The divot region 370 serves to block a surface current path, which connects the drain/channel/source regions to each other and has very low resistance. The divot region 370 is formed at an impurity density of 10¹⁵˜10¹⁶ cm⁻³, which is similar to the impurity density of the drain region 330. An implantation depth of the divot region 370 may be similar to that of the drain region 330 and be increased or decreased to maximize characteristics of the ESD protection device, as needed.

Further, a compensation region 380 is formed to surround the drain region 330 and the divot region 370 in order to compensate for current loss caused by the formation of the divot region 370. The compensation region 380 is formed by implanting P-type impurities at a density of about 10¹³ cm⁻³, which is similar to that of the drain drift region 360, and has a slightly deeper implantation depth than the drain drift region 360 such that a lower end of the compensation region 380 can penetrate the drain drift region 360, as shown in FIG. 5.

A ballistic region 400 is formed to promote flow of electric current in the depth direction of the device. The ballistic region 400 is formed centered on the drain region 330 by deeply implanting N-type impurities to reach the bottom of the P well region 310. As such, the ballistic region 400 is formed centered on the drain region 330 to completely surround the drain region 330 or to be positioned inside the drain region 330. As such, the formation of the ballistic region 400 provides an advantage of stronger induction of electric current in the depth direction of the device than any other direction.

A trajectory N-implant region 410 is formed on the bottom of the high P well 310 to maximize current induction of the ballistic region. The trajectory N-implant region 410 serves to connect the ballistic region 400 to the source region 340 at a depth of the ballistic region 400. The trajectory N-implant region 410 is formed by implanting N-type impurities such that the implanted N-type impurities can be present on the bottom of the device. In other words, the trajectory N-implant region 410 is formed to be located in the high voltage P well region 310 while being placed deeper than the drain drift region 360. The trajectory N-implant region 410 and the ballistic region 400 are formed in a pair to maximize the effect thereof. Advantageously, the depth of the trajectory N-implant region 410 is the same as the depth of the ballistic region 400.

In this embodiment, the DIADDDNMOS includes the ballistic region 400 and the trajectory N-implant region 410 to promote the flow of electric current in the depth direction of the device during operation of the NPN BJT, thereby realizing both high on-state resistance and high current immunity.

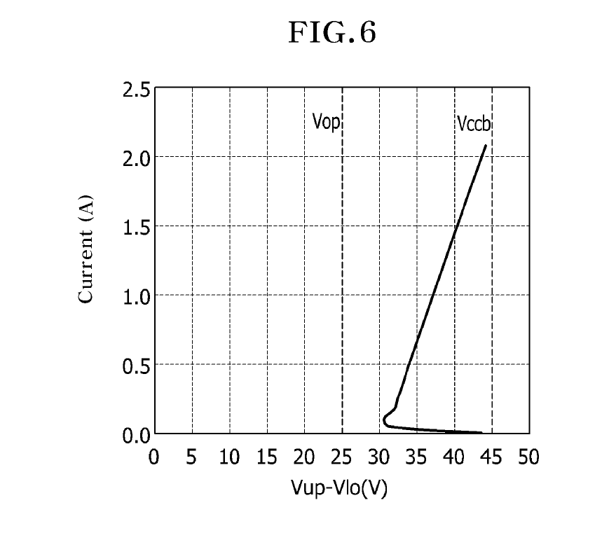

FIG. 6 is a graphical representation of voltage-current characteristics of an ESD protection device during normal operation and upon inflow of electrostatic current, according to the present disclosure.

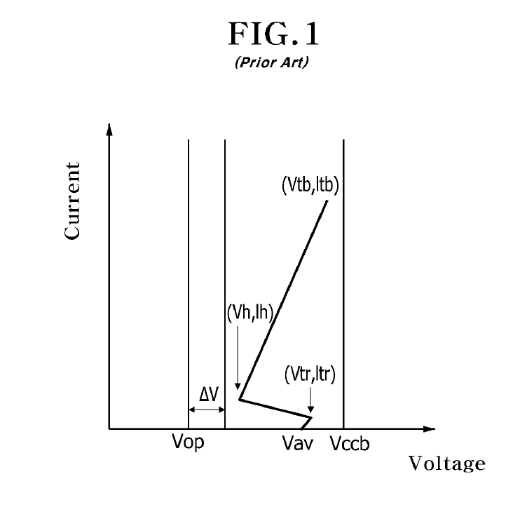

Compared with the graph shown in FIG. 1, the ESD protection device according to the present disclosure overcomes the problems of the existing DDDNMOS while satisfying the fundamental requirements of an ESD protection device for high voltage operation.

As such, according to the embodiments, the DIADDDNMOS ESD protection device including a divot region and a compensation region may overcome the problem of current crowding on the surface of the DDDNMOS device used as an ESD protection device. Further, the DIADDDNMOS device may provide a desired avalanche breakdown voltage and triggering voltage of an NPN BJT formed therein through suitable adjustment of a distance between the compensation region and the drain drift region.

Although some embodiments have been provided to illustrate the present disclosure, it should be understood that these embodiments are given by way of illustration only, and that various modifications, variations, and alternations can be made without departing from the spirit and scope of the present disclosure. The scope of the present disclosure should be limited only by the accompanying claims and equivalents thereof.

What is claimed is:

1. A double diffused drain N-type MOSFET (DDDNMOS) electrostatic discharge (ESD) protection device, in which a gate, a source region and a well-pickup region are connected to a ground terminal and a drain region is connected to a power terminal or individual input/output terminals, comprising:
a first conductive type well region formed in a semiconductor substrate;
a gate formed on the semiconductor substrate;
a second conductive type source region and a drain region formed in the well region at opposite sides of the gate;
a first conductive type well-pickup region formed at one side of the source region;
a second conductive type drain drift region formed in the well region to surround the drain region; and
a first conductive type divot region formed in the drain drift region between a side surface of the gate and the drain region.

2. The ESD protection device according to claim 1, further comprising: a second conductive type compensation region configured to surround the drain region and the divot region.

3. The ESD protection device according to claim 2, wherein the compensation region is formed deeper than the drain drift region such that a lower end of the compensation region penetrates the drain drift region.

4. The ESD protection device according to claim 2, wherein a distance between an edge of the compensation region and an edge of the drain drift region is adjusted to attain a desired avalanche breakdown voltage and triggering voltage of a bipolar transistor created in the device.

5. A double diffused drain N-type MOSFET (DDDNMOS) electrostatic discharge (ESD) protection device, in which a gate, a source region and a well-pickup region are connected to a ground terminal and a drain region is connected to a power terminal or individual input/output terminals, comprising:
a first conductive type well region formed in a semiconductor substrate;
a gate formed on the semiconductor substrate;
a second conductive type source region and a drain region formed in the well region at opposite sides of the gate;
a first conductive type well-pickup region formed at one side of the source region;
a first conductive type pocket region formed in the well region to surround the source region;
a second conductive type drain drift region formed in the well region to surround the drain region; and
a first conductive type divot region formed in the drain drift region between a side surface of the gate and the drain region.

6. The ESD protection device according to claim 5, further comprising: a second conductive type compensation region configured to surround the drain region and the divot region.

7. The ESD protection device according to claim 6, wherein the compensation region is formed deeper than the drain drift region such that a lower end of the compensation region penetrates the drain drift region.

8. The ESD protection device according to claim 6, wherein a distance between an edge of the compensation region and an edge of the drain drift region is adjusted to attain a desired avalanche breakdown voltage and triggering voltage of a bipolar transistor created in the device.

9. The ESD protection device according to claim 5, wherein an impurity implantation condition is adjusted to maximize an overlap margin between the pocket region and the source region while minimizing a depth margin of the picket region to the source region in order to suppress flow of electric current on a surface of the device while promoting the flow of electric current in a depth direction of the device.

10. The ESD protection device according to claim 5, further comprising: a second conductive type ballistic region formed centered on the drain region to surround the drain region or to be positioned inside the drain region.

11. The ESD protection device according to claim 10, wherein the ballistic region is formed centered on the drain region such that a bottom surface of the ballistic region is close to a bottom of the well region.

12. The ESD protection device according to claim 10, further comprising: a second conductive type trajectory region formed on the bottom of the well region to maximize current induction of the ballistic region.

13. The ESD protection device according to claim 12, wherein the trajectory region is formed in the well region so as to extend deeper than the drain drift region.
